(19) United States
(12) Patent Application Publication
(10) Pub. No.: US 2020/0044639 A1
(43) Pub. Date: Feb. 6, 2020

(54) LATCH CIRCUIT

(71) Applicant: Realtek Semiconductor Corporation, Hsinchu (TW)

(72) Inventors: Jian-Ru LIN, Nantou County (TW); Liang-Huan LEI, Kaohsiung (TW)

(21) Appl. No.: 16/519,266

(22) Filed: Jul. 23, 2019

(30) Foreign Application Priority Data
Jul. 31, 2018 (TW) 107126555

(51) Int. Cl. H03K 5/135; H03K 5/26; H03K 19/017; H03M 1/08; H03M 1/66; H03K 3/353

(52) U.S. Cl. CPC H03K 5/135; H03K 5/26; H03K 3/353; H03M 1/0872; H03M 1/66; H03K 19/017

(57) ABSTRACT

A latch circuit includes a switch circuit, an input circuit, and an output circuit. The switch circuit is coupled between a first power node and a second power node, and includes a non-inverting output node and an inverting output node. The input circuit couples with the non-inverting output node and the inverting output node, and conducts the non-inverting output node with the second power node according to a clock signal and a data signal. The output circuit couples with the non-inverting output node, the inverting output node, the first power node, and the second power node. The output circuit conducts the non-inverting output node with the first power node according to the clock signal and the data signal. When the data signal is switched, the switch circuit sets a conductive path from the first power node to the second power node as an open circuit.

### CROSS-REFERENCE TO RELATED APPLICATION

This application claims priority to Patent Application No. 107126555, filed in Taiwan on Jul. 31, 2018, which is herein incorporated by reference in its entirety.

### BACKGROUND

### Field of Invention

The present disclosure generally relates to a latch circuit. More particularly, the present disclosure relates to a latch circuit having a switch circuit capable of preventing the short circuit current.

### Description of Related Art

When the output signal of a traditional latch circuit is in a transient state (e.g., transited from a value of 1 to a value of 0), the high voltage source and the low voltage source of the latch circuit will be conducted with each other, and thus a short circuit current is generated. The short circuit current will render the output signal to have ripples, and components of a post-stage circuit (e.g., a digital-to-analog converter) can be damaged. In addition, the ripples cause the signal to noise ratio to be decreased, and also render the total harmonic distortion to be more serious.

### SUMMARY

The disclosure provides a latch circuit comprising a switch circuit, an input circuit, and an output circuit. The switch circuit is coupled between a first power node and a second power node, and comprises a non-inverting output node and an inverting output node. The input circuit is coupled with the non-inverting output node and the inverting output node, configured to receive a clock signal and a data signal, and configured to conduct the non-inverting output node with the second power node according to the clock signal and the data signal. The output circuit is coupled with the non-inverting output node and the inverting output node, and coupled with the first power node and the second power node. The output circuit is configured to conduct the non-inverting output node with the first power node according to the clock signal and the data signal to generate an output signal at the non-inverting output node. When voltage level of the data signal is switched, the switch circuit sets a conductive path from the first power node to the second power node as an open circuit.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a simplified block diagram of a digital-to-analog converting unit according to one embodiment of the present disclosure.

FIG. 2 is a circuit schematic diagram of a latch circuit according to one embodiment of the present disclosure.

FIG. 3 depicts simplified schematic waveforms of the latch circuit of FIG. 2 according to one embodiment of the present disclosure.

FIG. 4 is an enlarged view of some of the schematic waveforms in the first transient period.

FIG. 5 is a circuit schematic diagram of a latch circuit according to one embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

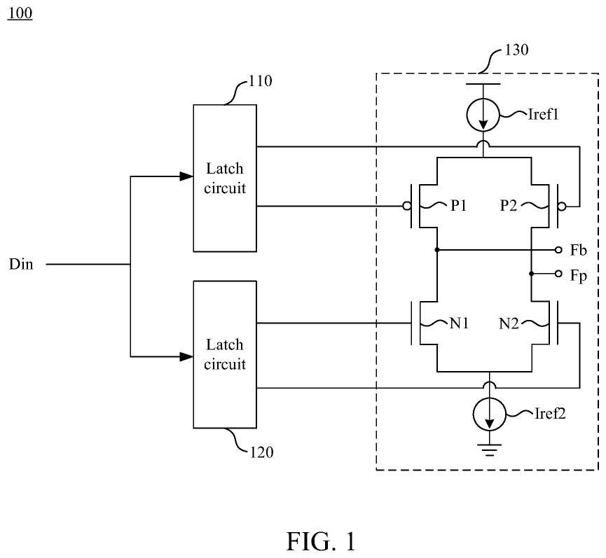

FIG. 1 is a simplified block diagram of a digital-to-analog converting unit 100 according to one embodiment of the present disclosure. The digital-to-analog converting unit 100 comprises a latch circuit 110, a latch circuit 120, and a digital-to-analog converter 130. The digital-to-analog converter 130 comprises a current source Iref1 a current source Iref2, a P-type transistor P1, a P-type transistor P2, an N-type transistor N1, and an N-type transistor N2. The transistors P1 and N1 are coupled with each other in a series connection between the current sources Iref1 and Iref2. The transistors P2 and N2 are also coupled with each other in a series connection between the current sources Iref1 and Iref2. For the sake of brevity, other functional blocks of the digital-to-analog converting unit 100 are not shown in FIG. 1.

The latch circuit 110 is configured to control the switching operations of the transistors P1 and P2 according to the data signal Din. The latch circuit 120 is configured to control the switching operations of the transistors N1 and N2 according to the data signal Din. Owing to the cooperative operation between the latch circuit 110 and the latch circuit 120, the digital-to-analog converter 130 may output a feedback signal Fb from a node between the transistors P1 and N1, and output an inverse feedback signal Fp from a node between the transistors P2 and N2.

In practice, the digital-to-analog converting unit 100 may be adapted in an analog-to-digital converter. The data signal Din may be generated by the analog-to-digital converter by using the various dynamic element matching algorithms. The analog-to-digital converter may modify the output thereof according to the feedback signal Fb and the inverse feedback signal Fp, so that the output error caused by the mismatching between the components of the analog-to-digital converter may be reduced.

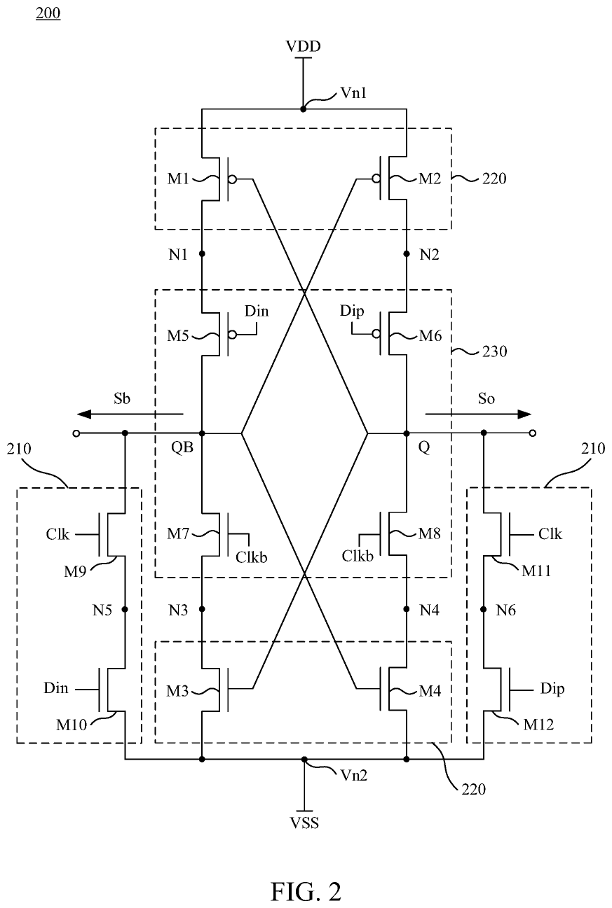

FIG. 2 is a circuit schematic diagram of a latch circuit 200 according to one embodiment of the present disclosure. The latch circuit 200 may be the latch circuit 110 or the latch circuit 120 of FIG. 1. The latch circuit 200 comprises an input circuit 210, an output circuit 220, and a switch circuit 230. The switch circuit 230 is coupled between a first power node Vn1 and a second power node Vn2, and comprises a non-inverting output node Q and an inverting output node QB. The input circuit 210 is coupled with the non-inverting output node Q and the inverting output node QB, and is configured to receive a clock signal Clk and a data signal Din. The input circuit 210 is further configured to conduct the non-inverting output node Q with the second power node Vn2 according to the clock signal Clk and the data signal Din. The output circuit 220 is coupled with the non-inverting output node Q and the inverting output node QB, and is coupled with the first power node Vn1 and the second power node Vn2. The output circuit 220 is configured to conduct the non-inverting output node Q with the first power node Vn1 according to the clock signal Clk and the data signal Din, so as to generate an output signal So at the non-inverting output node Q.

In addition, the latch circuit 200 is configured to receive a first reference voltage VDD from the first power node Vn1, and to receive a second reference voltage VSS from the second power node Vn2. The voltage level of the first reference voltage VDD is higher than the voltage level of the second reference voltage VSS.

The output circuit 220 comprises first through fourth transistors M1-M4. The first transistor M1 is coupled between the first power node Vn1 and the first node point N1, and a control node thereof is coupled with the non-inverting output node Q. The second transistor M2 is coupled between the first power node Vn1 and the second node point N2, and a control node thereof is coupled with the inverting output node QB. The third transistor M3 is coupled between the second power node Vn2 and the third node point N3, and a control node thereof is coupled with the non-inverting output node Q. The fourth transistor M4 is coupled between the second power node Vn2 and the fourth node point N4, and a control node thereof is coupled with the inverting output node QB.

The output circuit 220 is configured to output the output signal So through the non-inverting output node Q, and to output the inverse output signal Sb through the inverting output node QB. The phase of the output signal So is opposite to the phase of the inverse output signal Sb.

The switch circuit 230 comprises fifth through eighth transistors M5-M8. The fifth transistor M5 is coupled between the first node point N1 and the inverting output node QB, and a control node thereof is configured to receive the data signal Din. The sixth transistor M6 is coupled between the second node point N2 and the non-inverting output node Q, and a control node thereof is configured to receive the inverse data signal Dip. The phase of the data signal Din is opposite to the phase of the inverse data signal Dip. The seventh transistor M7 is coupled between the third node point N3 and the inverting output node QB, and a control node thereof is configured to receive the inverse clock signal Clkb. The phase of the clock signal Clk is opposite to the phase of the inverse clock signal Clkb. The eighth transistor M8 is coupled between the fourth node point N4 and the non-inverting output node Q, and a control node thereof is configured to receive the inverse clock signal Clkb.

The input circuit 210 comprises ninth through twelfth transistors M9-M12. The ninth transistor M9 is coupled between the inverting output node QB and the fifth node point N5, and a control node thereof is configured to receive the clock signal Clk. The tenth transistor M10 is coupled between the fifth node point N5 and the second power node Vn2, and a control node thereof is configured to receive the data signal Din. The eleventh transistor M11 is coupled between the non-inverting output node Q and the sixth node point N6, and a control node thereof is configured to receive the clock signal Clk. The twelfth transistor M12 is coupled between the sixth node point N6 and the second power node Vn2, and a control node thereof is configured to receive the inverse data signal Dip.

In other words, the ninth transistor M9 and the tenth transistor M10 are coupled with each other in a series connection between the inverting output node QB and the second power node Vn2. The eleventh transistor M11 and the twelfth transistor M12 are coupled with each other in a series connection between the non-inverting output node Q and the second power node Vn2.

In some embodiment, the positions of the ninth transistor M9 and the tenth transistor M10 may be swapped, and the positions of the eleventh transistor M11 and the twelfth transistor M12 may also be swapped.

In practice, the first transistor M1, the second transistor M2, the fifth transistor M5, and the sixth transistor M6 may be realized with various suitable types of P-type transistors. The third transistor M3, the fourth transistor M4, and the seventh through twelfth transistors M7-M12 may be realized with various suitable types of N-type transistors.

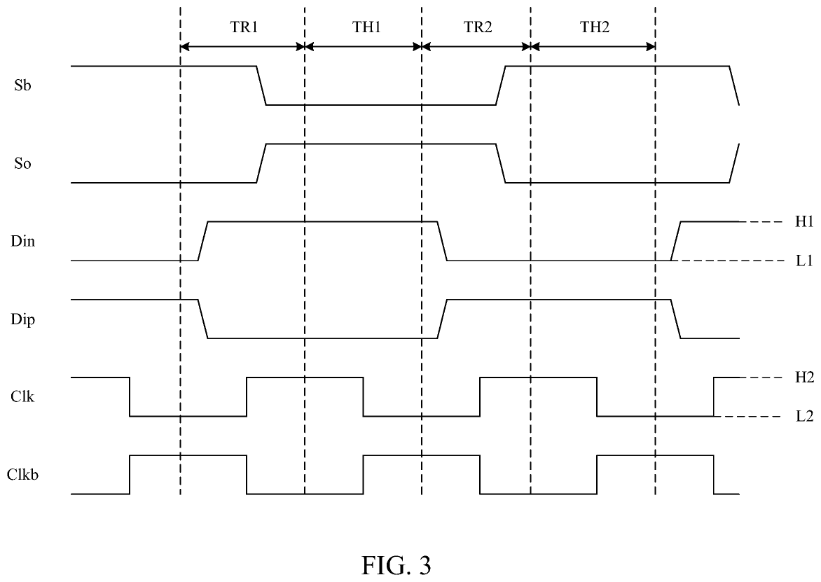

FIG. 3 depicts simplified schematic waveforms of the latch circuit 200 of FIG. 2 according to one embodiment of the present disclosure. During the first transient period TR1, it is hereinafter assumed that the latch circuit 200 previously generates the output signal So having a voltage level equal to the second reference voltage VSS, and previously generate the inverse output signal Sb having a voltage level equal to the first reference voltage VDD (i.e., the latch circuit 200 previously stores a value of 0 at the non-inverting output node Q, and previously stores a value of 1 at the inverting output node QB).

When the data signal Din is switched from the first low voltage level L1 to the first high voltage level H1, the clock signal Clk would be temporarily maintained at the second low voltage level L2. In this situation, the first transistor M1, the fourth transistor M4, the sixth transistor M6, the seventh transistor M7, the eighth transistor M8, the tenth transistor M10, and the eleventh transistor M11 are in a conducted state, and the second transistor M2, the third transistor M3, the fifth transistor M5, the ninth transistor M9, and the twelfth transistor M12 are in a switched-off state.

Then, the clock signal Clk is switched from the second low voltage level L2 to the second high voltage level H2. Therefore, the ninth transistor M9 and the eleventh transistor M11 are switched to the conducted state, and the seventh transistor M7 and the eighth transistor M8 are switched to the switched-off state. Therefore, the inverse output signal Sb corresponding to the inverting output node QB is equal to the second reference voltage VSS, and thus the output signal So corresponding to the non-inverting output node Q is equal to the first reference voltage VDD (i.e., the non-inverting output node Q outputs a value of 1, and the inverting output node QB outputs a value of 0).

In other words, the data signal Din is first switched from the first low voltage level L1 to the first high voltage level H1, and the clock signal Clk is then switched from the second low voltage level L2 to the second high voltage level H2.

Thus, the fifth transistor M5 is first switched to the switched-off state, and the ninth transistor M9 is then switched to the conducted state. Accordingly, a conductive path, from the first power node Vn1 to the second power node Vn2, is maintained as an open circuit during the first transient period TR1. As a result, a short circuit current flowing from the first power node Vn1 to the second power node Vn2 can be prevented.

During the first holding period TH1, the data signal Din is maintained at the first high voltage level H1. In this situation, even if the voltage level of the clock signal Clk is switched, the output signal So will still remain at the first reference voltage VDD, and the inverse output signal Sb will still remain at the second reference voltage VSS (i.e., the non-inverting output node Q stores the value of 1, and the inverting output node QB stores the value of 0).

During the second transient period TR2, when the data signal Din is switched from the first high voltage level H1 to the first low voltage level L1, the clock signal Clk would be temporarily maintained at the second low voltage level L2. In this situation, the second transistor M2, the third transistor M3, the fifth transistor M5, the seventh transistor M7, the eighth transistor M8, and the twelfth transistor M12 are in a conducted state, and the first transistor M1, the fourth transistor M4, the sixth transistor M6, the ninth transistor M9, the tenth transistor M10, and the eleventh transistor M11 are in a switch-off state.

Then, the clock signal Clk is switched from the second low voltage level L2 to the second high voltage level H2. Therefore, the ninth transistor M9 and the eleventh transistor M11 are switched to the conducted state, and the seventh transistor M7 and the eighth transistor M8 are switched to the switched-off state. As a result, the output signal So corresponding to the non-inverting output node Q is equal to the second reference voltage VSS, and thus the inverse output signal Sb corresponding to the inverting output node QB is equal to the first reference voltage VDD (i.e., the non-inverting output node Q outputs the value of 0, and the inverting output node QB outputs the value of 1).

In other words, the data signal Din is first switched from the first high voltage level H1 to the first low voltage level L1, and the clock signal Clk is then switched from the second low voltage level L2 to the second high voltage level H2.

Thus, the sixth transistor M6 is first switched to the switched-off state, and the eleventh transistor M11 is then switched to the conducted state. Accordingly, the conductive path, from the first power node Vn1 to the second power node Vn2, is maintained as the open circuit during the second transient period TR2. As a result, the short circuit current flowing from the first power node Vn1 to the second power node Vn2 can be prevented.

In addition, during the second transient period TR2, between the change of the voltage level of the data signal Din and the change of the voltage level of the clock signal Clk, the non-inverting output node Q is temporarily in a floating state since the sixth transistor M6 is switched to the switched-off state. However, the latch circuit 200 is operated under a high frequency, and thus the parasitic capacitor of the non-inverting output node Q is sufficient for maintaining the voltage level thereof when the non-inverting output node Q is in the floating state. Therefore, the output signal So can be stably maintained at the first reference voltage VDD (i.e., the non-inverting output node Q can stably stores the value of 1).

During the second holding period TH2, the data signal Din is maintained at the first low voltage level L1. In this situation, even if the voltage level of the clock signal Clk is switched, the output signal So will remain at the second reference voltage VSS, and the inverse output signal Sb will remain at the first reference voltage VDD (i.e., the non-inverting output node Q stores the value of 0, and the inverting output node QB stores the value of 1).

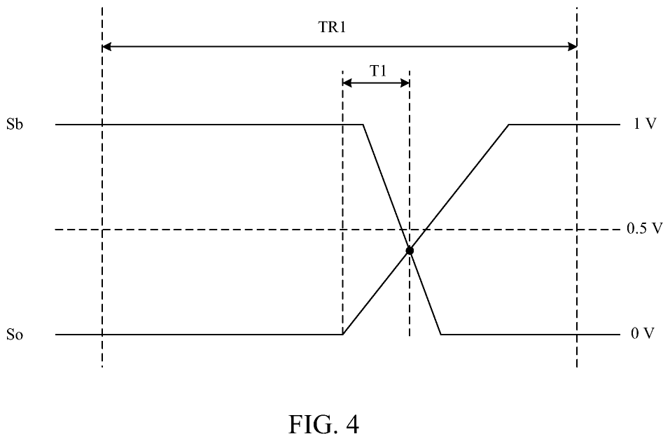

In this embodiment, a point of intersection between the output signal So and the inverse output signal Sb may be determined by modifying the width-to-length ratio of the first transistor M1 and/or the second transistor M2, which will be further described in the following by reference to FIGS. 2 and 4. FIG. 4 is an enlarged view of some of the schematic waveforms in the first transient period TR1 of FIG. 3. As aforementioned, in first transient period TR1, when the voltage level of the clock signal Clk is switched and the voltage variation of the inverse output signal Sb is transmitted to the control node of the second transistor M2, the second transistor M2 is switched to the conducted sate to charge the non-inverting output node Q.

By modifying the width-to-length ratio of the second transistor M2, the response time required for the second transistor M2 to be switched form the switched-off state to the conducted state may be determined, and the charging speed of the second transistor M2 when charging the non-inverting output node Q may also be determined. In details, the response time and the charging speed of the second transistor M2 are negatively correlated to the width-to-length ratio of the second transistor M2.

Therefore, in the first transient period TR1, when the voltage level of the clock signal Clk is switched, a time interval T1, required by the output signal So to rise to the point of intersection, is negatively correlated to the width-to-length ratio of the second transistor M2.

Similarly, in the second transient period TR2, when the voltage level of the clock signal Clk is switched, a time interval, required by the inverse output signal Sb to rise to the point of intersection, is negatively correlated to the width-to-length ratio of the first transistor M1.

In the situation that the latch circuit 200 is the latch circuit 110 configured to control the transistors P1 and P2, the point of intersection between the output signal So and the inverse output signal Sb may be set to be lower than a middle voltage (e.g., 0.5 V) shown in FIG. 4. As a result, it is ensured that the transistors P1 and P2 will not be switched off simultaneously, and the stability of the digital-to-analog converter 130 is guaranteed.

Similarly, in the situation that the latch circuit 200 is the latch circuit 120 configured to control the transistors N1 and N2, the point of intersection between the output signal So and the inverse output signal Sb may be set to be higher than the middle voltage shown in FIG. 4. As a result, it is ensured that the transistors N1 and N2 will not be switched off simultaneously.

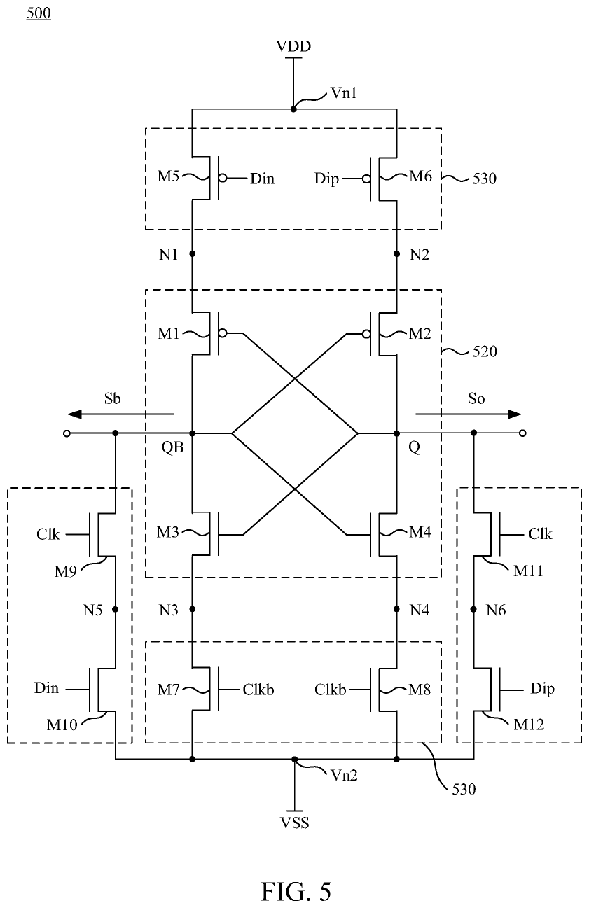

FIG. 5 is a circuit schematic diagram of a latch circuit 500 according to one embodiment of the present disclosure. The latch circuit 500 may be the latch circuit 110 or the latch circuit 120 of FIG. 1. The latch circuit 500 comprises an input circuit 210, an output circuit 520, and a switch circuit 530.

The output circuit 520 comprises first through fourth transistors M1-M4. The first transistor M1 is coupled between the first node point N1 and the inverting output node QB, and a control node thereof is coupled with the non-inverting output node Q. The second transistor M2 is coupled between the second node point N2 and the non-inverting output node Q, and a control node thereof is coupled with the inverting output node QB. The third transistor M3 is coupled between the third node point N3 and the inverting output node QB, and a control node thereof is coupled with the non-inverting output node Q. The fourth transistor is coupled between the fourth node point N4 and the non-inverting output node Q, and a control thereof is coupled with the inverting output node QB.

The switch circuit 530 comprises fifth through eighth transistors M5-M8. The fifth transistor M5 coupled between the first node point N1 and the first power node Vn1, and a control node thereof is configured to receive the data signal Din. The sixth transistor M6 is coupled between the second node point N2 and the first power node Vn1, and a control node thereof is configured to receive the inverse data signal Dip. The seventh transistor M7 is coupled between the third node point N3 and the second power node Vn2, and a control node thereof is configured to receive the inverse clock signal Clkb. The eighth transistor M8 is coupled between the fourth node point N4 and the second power node Vn2, and a control node thereof is configured to receive the inverse clock signal Clkb.

The foregoing descriptions regarding the implementations, connections, operations, and related advantages of other corresponding functional blocks in the latch circuit 200 are also applicable to the latch circuit 500. For the sake of brevity, those descriptions will not be repeated here.

As can be appreciate from the foregoing descriptions, when the voltage level of the data signal Din is switched, the latch circuits 200 and 500 will set the conductive path from the first power node Vn1 to the second power node Vn2 as the open circuit. Therefore, when the non-inverting output node Q or the inverting output node QB is in a transient state, the latch circuits 200 and 500 can prevent a short circuit current flowing from the first power node Vn1 to the second power node Vn2.

In other words, the latch circuits 200 and 500 can increase the signal to noise ratio, and can also mitigate the total harmonic distortion.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The term “couple” is intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The term “and/or” may comprise any and all combinations of one or more of the associated listed items. In addition, the singular forms “a,” “an,” and “the” herein are intended to comprise the plural forms as well, unless the context clearly indicates otherwise.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A latch circuit, comprising:
a switch circuit, coupled between a first power node and a second power node, and comprising a non-inverting output node and an inverting output node;
an input circuit, coupled with the non-inverting output node and the inverting output node, configured to receive a clock signal and a data signal, and configured to conduct the non-inverting output node with the second power node according to the clock signal and the data signal; and
an output circuit, coupled with the non-inverting output node and the inverting output node, and coupled with the first power node and the second power node, wherein the output circuit is configured to conduct the non-inverting output node with the first power node according to the clock signal and the data signal to generate an output signal at the non-inverting output node,
wherein when voltage level of the data signal is switched, the switch circuit sets a conductive path from the first power node to the second power node as an open circuit.

2. The latch circuit of claim 1, wherein the output circuit is further configured to generate an inverse output signal opposite to the output signal,
wherein when voltage level of the clock signal is switched, the output circuit determines a point of intersection between the output signal and the inverse output signal.

3. The latch circuit of claim 1, wherein the output circuit comprises:
a first transistor, couples between the first power node and a first node point, wherein a control node of the first transistor is coupled with the non-inverting output node;
a second transistor, coupled between the first power node and a second node point, wherein a control node of the second transistor is coupled with the inverting output node;
a third transistor, coupled between the second power node and a third node point, wherein a control node of the third transistor is coupled with the non-inverting output node; and
a fourth transistor, coupled between the second power node and a fourth node point, wherein a control node of the fourth transistor is coupled with the inverting output node.

4. The latch circuit of claim 3, wherein the output circuit is further configured to generate an inverse output signal opposite to the output signal,
wherein when voltage level of the clock signal is switched, the output signal rises to a point of intersection between the output signal and the inverse output signal during a time interval, and the time interval is negatively correlated with a width-to-length ratio of the second transistor.

5. The latch circuit of claim 3, wherein the switch circuit comprises:
a fifth transistor, coupled between the first node point and the inverting output node, wherein a control node of the fifth transistor is configured to receive the data signal;
a sixth transistor, coupled between the second node point and the non-inverting output node, wherein a control node of the sixth transistor is configured to receive an inverse data signal opposite to the data signal;
a seventh transistor, coupled between the third node point and the inverting output node, wherein a control node of the seventh transistor is configured to receive an inverse clock signal opposite to the clock signal; and
an eighth transistor, coupled between the fourth node point and the non-inverting output node, wherein a control node of the eighth transistor is configured to receive the inverse clock signal.

6. The latch circuit of claim 5, wherein the input circuit comprises:
a ninth transistor, wherein a control node of the ninth transistor is configured to receive the clock signal;
a tenth transistor, wherein a control node of the tenth transistor is configured to receive the data signal, and the ninth transistor and the tenth transistor is coupled with each other in a series connection between the inverting output node and the second power node;
an eleventh transistor, wherein a control node of the eleventh transistor is configured to receive the clock signal; and
a twelfth transistor, wherein a control node of the twelfth transistor is configured to receive the inverse data signal, and the eleventh transistor and the twelfth transistor is coupled with each other in a series connection between the non-inverting output node and the second power node.

7. The latch circuit of claim 1, wherein the output circuit comprises:
a first transistor, coupled between a first node point and the inverting output node, wherein a control node of the first transistor is coupled with the non-inverting output node;
a second transistor, coupled between a second node point and the non-inverting output node, wherein a control node of the second transistor is coupled with the inverting output node;
a third transistor, coupled between a third node point and the inverting output node, wherein a control node of the third transistor is coupled with the non-inverting output node; and
a fourth transistor, coupled between a fourth node point and the non-inverting output node, wherein a control node of the fourth transistor is coupled with the inverting output node.

8. The latch circuit of claim 7, wherein the output circuit is further configured to generate an inverse output signal opposite to the output signal,
wherein when voltage level of the clock signal is switched, the output signal rises to a point of intersection between the output signal and the inverse output signal during a time interval, and the time interval is negatively correlated with a width-to-length ratio of the second transistor.

9. The latch circuit of claim 7, wherein the switch circuit comprises:
a fifth transistor, coupled between the first node point and the first power node, wherein a control node of the fifth transistor is configured to receive the data signal;
a sixth transistor, coupled between the second node point and the first power node, wherein a control node of the sixth transistor is configured to receive an inverse data signal opposite to the data signal;
a seventh transistor, coupled between the third node point and the second power node, wherein a control node of the seventh transistor is configured to receive the clock signal; and
an eighth transistor, coupled between the fourth node point and the second power node, wherein a control node of the eighth transistor is configured to receive the clock signal.

10. The latch circuit of claim 9, wherein the input circuit comprises:
a ninth transistor, wherein a control node of the ninth transistor is configured to receive the clock signal;
a tenth transistor, wherein a control node of the tenth transistor is configured to receive the data signal, and the ninth transistor and the tenth transistor is coupled with each other in a series connection between the inverting output node and the second power node;
an eleventh transistor, wherein a control node of the eleventh transistor is configured to receive the clock signal; and
a twelfth transistor, wherein a control node of the twelfth transistor is configured to receive the inverse data signal, and the eleventh transistor and the twelfth transistor is coupled with each other in a series connection between the non-inverting output node and the second power node.

11. The latch circuit of claim 10, wherein the fifth transistor is first switched to a switched-off state to set the conductive path as the open circuit, and the ninth transistor is then switched to a conducted state.

12. The latch circuit of claim 10, wherein the data signal is first switched from a first low voltage level to a first high voltage level, and the clock signal is then switched from a second low voltage level to a second high voltage level.
